(19) United States
(12) Patent Application Publication
(10) Pub. No.: US 2010/0112468 A1
(43) Pub. Date: May 6, 2010

(54) SELF-CORRECTING SUBSTRATE SUPPORT SYSTEM FOR FOCUS CONTROL IN EXPOSURE SYSTEMS

(76) Inventors: Andre Poock, Malschwitz (DE); Rene Wirtz, Stuttgart (DE)

Correspondence Address: WILLIAMS, MORGAN & AMERSON, 10333 RICHMOND, SUITE 1100, HOUSTON, TX, 77042, US

(21) Appl. No.: 12/575,003

(22) Filed: Oct. 7, 2009

(30) Foreign Application Priority Data
Oct. 31, 2008 (DE) 10 2008 054 072.2

(51) Int. Cl. G03F 7/20; G03B 27/58; G03B 27/68

(52) U.S. Cl. 430/30; 355/72; 355/52; 430/322

(57) ABSTRACT

A substrate support system for process tools, such as lithography tools, comprises a configuration in which a local height level adjustment may be accomplished. Thus, upon detecting a non-allowable height level, the corresponding portion of the substrate support surface may be re-adjusted. Hence, the focus conditions of advanced exposure processes may be significantly enhanced, thereby providing superior process results and also increasing tool utilization.

### BACKGROUND OF THE INVENTION

1. Field of the Invention

Generally, the present disclosure relates to the field of fabricating microstructures, such as integrated circuits, and, more particularly, to adjusting focus during exposure processes.

2. Description of the Related Art

The fabrication of microstructures, such as integrated circuits, requires tiny regions of precisely controlled size to be formed in a material layer of an appropriate substrate, such as a silicon substrate, a silicon-on-insulator (SOI) substrate or other suitable carrier materials. These tiny regions of precisely controlled size are generated by patterning the material layer by performing lithography, etch, implantation, deposition, oxidation processes and the like, wherein, typically, at least in a certain stage of the patterning process, a mask layer may be formed over the material layer to be treated to define these tiny regions. Generally, a mask layer may consist of or may be formed by means of a layer of radiation sensitive material, such as photoresist, that is patterned by a lithographic process, typically a photolithography process. During the photolithography process, the radiation sensitive material or resist may be applied to the substrate surface and then selectively exposed to ultraviolet radiation through a corresponding lithography mask, such as a reticle, thereby imaging the reticle pattern into resist layer to form a latent image therein. After “developing” the photoresist or any other radiation sensitive material, depending on the type of resist or radiation sensitive material, positive resist or negative resist, the exposed portions or the non-exposed portions are removed to form the required pattern in the layer of photoresist or radiation sensitive material. Based on this resist pattern, actual device patterns may be formed by further manufacturing processes, such as etch, implantation, anneal processes and the like. Since the dimensions of the patterns in sophisticated integrated microstructure devices are steadily decreasing, the equipment used for patterning device features have to meet very stringent requirements with regard to resolution and overlay accuracy of the involved fabrication processes. In this respect, resolution is considered as a measure for specifying the consistent ability to print minimum size images under conditions of predefined manufacturing variations. One important factor in improving the resolution is represented by the lithography process, in which patterns contained in the photo mask or reticle are optically transferred to the substrate via an optical imaging system. Therefore, great efforts are made to steadily improve optical properties of the lithography system, such as numerical aperture, depth of focus and wavelength of the light source used.

Lithography processes are one of the most critical process steps during the fabrication of microstructure devices such as integrated circuits. Moreover, the lithography process may typically provide enhanced control capabilities as the process is typically performed stepwise for each individual substrate, that is, a plurality of individual imaging steps are usually performed for each substrate, thereby enabling individual control of each single imaging step. Consequently, across-wafer uniformity may be controlled by appropriately adapting process parameters of the individual imaging steps. In addition, the lithography process has a somewhat unique position in the entire manufacturing flow in that the process output of the lithography process may be assessed and the lithography process may be repeated when specific process margins are not achieved. On the other hand, lithography is a highly cost-intensive process and undue re-processing of out of control substrates may substantially contribute to overall production costs. One critical aspect in the lithography process is, in addition to appropriate alignment of the reticle pattern with respect to the substrate, the adjustment of the appropriate depth of focus, since the range for the available focus depth is related to the exposure wavelength and the numerical aperture, wherein, for a given numerical aperture, a reduced exposure wavelength leads to a reduced depth of focus. Thus, with ever decreasing features sizes in modern microstructures, such as integrated circuits, calling for shorter exposure wavelengths, the probability for grossly defocused exposure fields, which may also be referred to as “hot spots,” increases, thereby resulting in pronounced line width variations for the corresponding device feature on the substrate. Since many inspection and overlay measurement techniques may not very efficiently detect such hot spot errors, thereby significantly contributing to yield losses, since a corresponding portion of the substrate may not meet the associated device specifications, significant efforts have been made to reliably detect corresponding out of focus portions of a substrate, which, according to recent developments, may even be accomplished prior to actually exposing the substrates. For example, in modern exposure systems, substrate support systems may be used in which two substrate holders may receive corresponding substrates, one of which may be processed while the other one may be subjected to corresponding automatic alignment procedures, which may also include corresponding measurement procedures for determining out of focus positions on the substrate. Thus, based on knowledge corresponding out of focus positions, respective substrates may be marked for re-working and/or the corresponding automatic alignment procedures may be performed to attempt to reduce the number of out of focus positions on a substrate by using well-established alignment features. For instance, in conventional systems, the height of the substrate as a whole, as well as two independent tilt angles, may be varied in order to appropriately position the corresponding exposure fields of the substrate for the subsequent step and scan process.

Although significant advantages may be gained by obtaining measurement data with respect to out of focus exposure fields, nevertheless, a corresponding re-working of the substrates may add to increased overall production costs.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to systems and methods in which positioning a substrate for a subsequent exposure process may be enhanced by enabling an individual adjustment of the height position of a plurality of substrate portions so that an enhanced adaptation of the local height position, for instance with respect to maintaining the surface portion under consideration within desired focus range, may be enhanced. Thus, by providing an additional degree of freedom in selecting an appropriate position for the subsequent exposure, the number of out of focus positions within a substrate may be significantly reduced, thereby contributing to reduced overall production costs. Furthermore, in some illustrative aspects disclosed herein, momentary height positions may be determined and may be appropriately adjusted prior to actually exposing the substrate portion, thereby reducing respective non-productive times of expensive lithography tools since corresponding maintenance activities, for instance with respect to cleaning substrate support surfaces, wafer back sides and the like, may be significantly reduced, since the corresponding profile of the substrate support surface may be adapted to the detected momentary profile, thereby providing the possibility of maintaining the various substrate portions within the specified focus range. Additionally, enhanced focus control may be achieved with respect to higher order systematic focus errors, for instance due to small scale topography differences in the exposure medium such as the substrates of integrated circuit devices and the like, which may not be achieved by currently available systems in which the height level of the substrate holder as a whole and two orthogonal tilt angles may be controlled. Consequently, by appropriately adjusting the focus conditions in a highly locally resolved manner, increased design flexibility for sophisticated microstructure devices may be achieved, since corresponding influences of local focus non-uniformities may no longer have to be compensated for by corresponding design measures, for instance by avoiding critical device features in the vicinity of corresponding topography discrepancies and the like.

One illustrative substrate support system of an exposure tool disclosed herein comprises a plurality of support surface portions configured to receive a substrate to be exposed, wherein each of the plurality of support surface portions is individually adjustable in its height position. The substrate support system further comprises an actuation system connected to the plurality of support surface portions so as to initiate adjustment of the height position of each of the plurality of support surface portions on the basis of a control signal.

One illustrative exposure system disclosed herein comprises an imaging unit comprising a radiation source and an optical system. Furthermore, the exposure system comprises a substrate support system configured to receive and hold in place a substrate to be exposed, wherein the substrate support system comprises a plurality of support surface portions configured to receive a substrate to be exposed. Moreover, each of the plurality of support surface portions is individually adjustable in its height position. The substrate support system further comprises an actuation system connected to the plurality of support surface portions so as to initiate adjustment of the height position of each of the plurality of support surface portions on the basis of a control signal.

One illustrative method for exposing a substrate comprises receiving the substrate on a substrate support surface of a substrate support system. Furthermore, a height level of at least one portion of the substrate support surface is individually adjusted relative to at least one other portion of the substrate support surface. Finally, the method comprises exposing the substrate on the basis of the individually adjusted height level of the at least one portion of the substrate support surface.

### BRIEF DESCRIPTION OF THE DRAWINGS

The disclosure may be understood by reference to the following description taken in conjunction with the accompanying drawings, in which like reference numerals identify like elements, and in which:

FIGS. 1a and 1b schematically illustrate a substrate support system in two different operating stages in which the height level of a plurality of portions or elements of the corresponding substrate support surface may be individually controlled, according to illustrative embodiments;

FIG. 1c schematically illustrates a top view of a substrate support surface in which an individual adjustment of height positions may be accomplished by a piezoelectric material in combination with a selective application of a voltage, according to illustrative embodiments;

FIGS. 1d-1e schematically illustrate a substrate support system in which a local temperature control may be used in combination with a corresponding appropriate thermal expansion behavior in order to obtain an individual height adjustment capability, according to still other illustrative embodiments;

FIG. 1f schematically illustrates the substrate support system wherein energy may be deposited on a material in a selective manner, for instance based on high frequency energy, so as to obtain a local adaptation of a material characteristic, such as the thermal expansion thereof, according to still further illustrative embodiments;

FIG. 1g schematically illustrates the substrate support system according to further illustrative embodiments in which measurement data may be obtained for the momentary height level of a substrate which may then be adjusted on the basis of a corresponding height correction data; and

FIG. 1h schematically illustrates an exposure system comprising enhanced focus setting capabilities on the basis of a substrate support system with individual height adjustment capabilities, according to still other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to techniques and systems for enhancing the positioning of a substrate that is to be processed in a process tool for processing substrates according to microstructure engineering technologies. For this purpose, a substrate holder or substrate support system may be configured such that a height level of at least some substrate portions may be adjusted individually, for instance in view of contaminating particles that may be present on the substrate support surface and/or the back side of the substrate under consideration, so that a desired enhanced surface topography may be obtained at the front side of the substrate to be treated. For example, lithography processes are well-established manufacturing techniques in processing microstructure devices in which the ongoing shrinkage of critical device features may result in very restrictive constraints with respect to an allowable range of depth of focus of the imaging system, which may result in additional production costs, for instance with respect to non-productive times of very cost-intensive lithography tools due to maintenance activity, while in other cases a significant amount of the unproductive time may be used for re-working improperly exposed substrates. In this case, the individual adjustment of the height position of at least a plurality of surface portions of a corresponding substrate support surface may provide a significantly increased degree of freedom, for instance for compensating for height differences caused by particles and the like, thereby no longer requiring corresponding maintenance activities or at least significantly reducing the number of corresponding activities. Additionally, topography differences in certain substrate areas may be compensated, at least to a certain degree, thereby enhancing overall performance of the exposure process. For example, typically, in sophisticated integrated circuits, different height levels may occur in chip internal regions compared to frame regions, in which a plurality of test structures and the like may be formed, thereby increasingly rendering any measurement data obtained therefrom as less reliable, since critical device features within the die area may have different configurations compared to critical features of the test structures due to different focus conditions in these substrate areas. Thus, the individual height adjustment across the substrate may provide the correction or at least reduction of corresponding higher order errors, thereby contributing to enhanced performance of the overall lithography process and thus of corresponding microstructure devices. Thus, the present disclosure may be highly advantageous in the context of exposure tools and corresponding process techniques, since here a significant improvement of the focus conditions may be obtained in a local manner, thereby enhancing overall performance of the corresponding device features and also increasing flexibility of designing respective devices and manufacturing processes, as previously discussed. It should be appreciated, however, that also in other critical application processes or processing microstructure devices, the adjustment of the surface topography in a highly local manner may be advantageous in order to enhance process throughput and process output. For example, in sophisticated imprint technologies in which a material may be controllably deformed in order to transfer a certain pattern into the material layer may also benefit from an enhanced surface topography. Thus, unless explicitly set forth in the appended claims and any embodiments of the specification, the principles disclosed herein should not be construed as being restricted to the application to exposure tools.

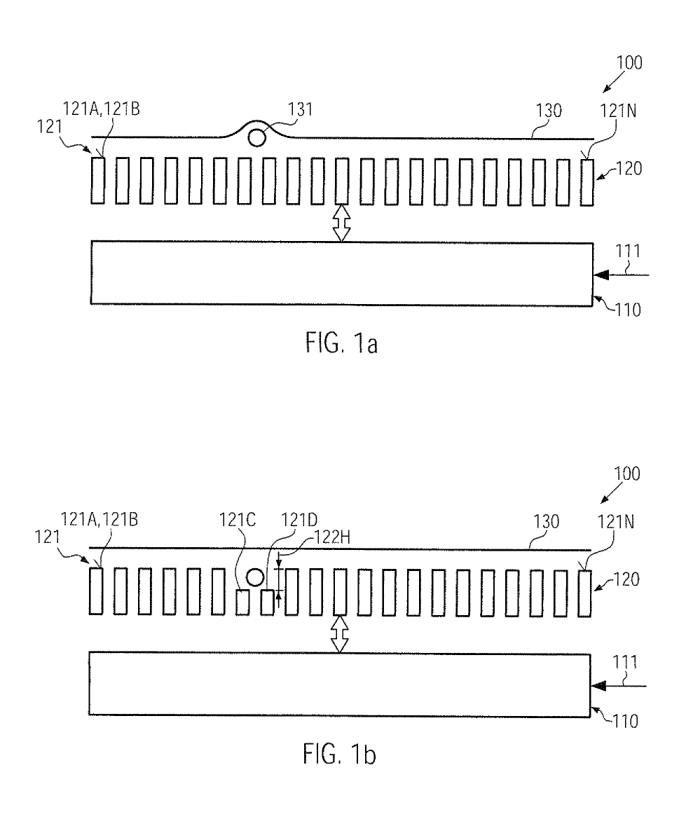

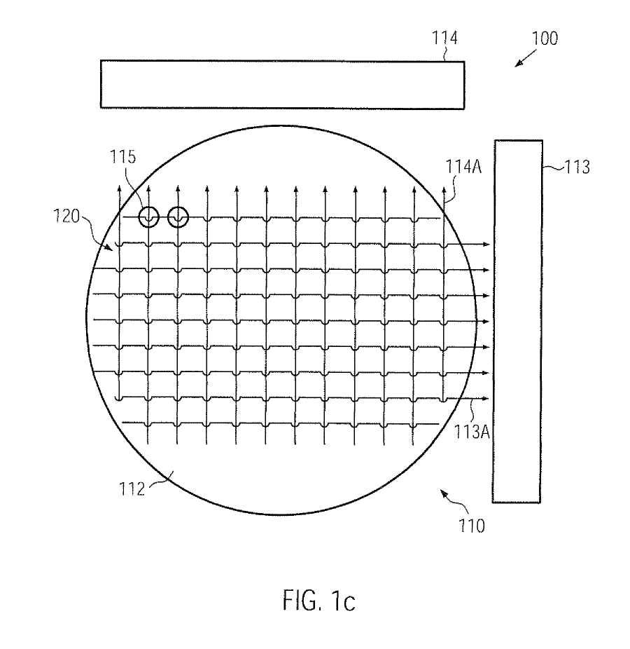

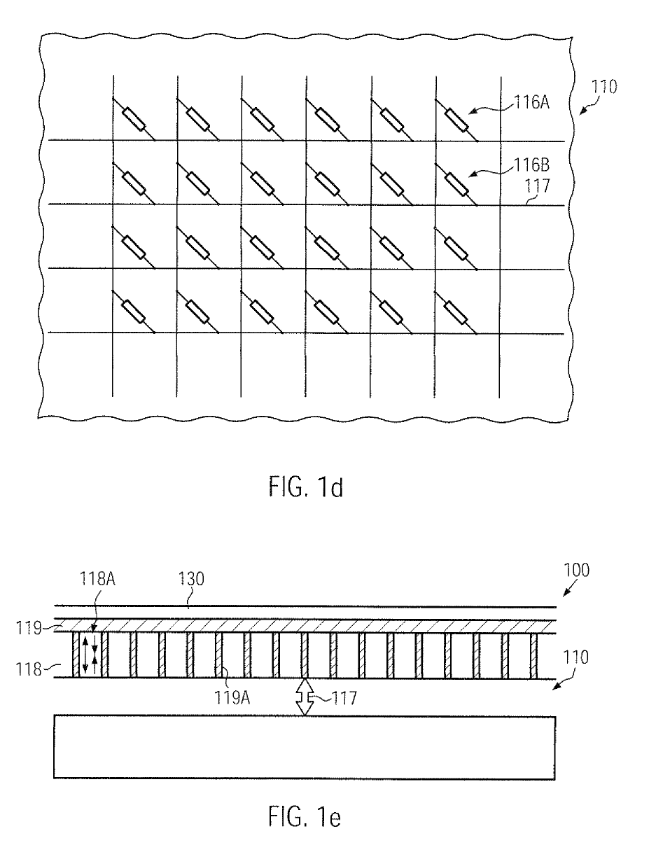

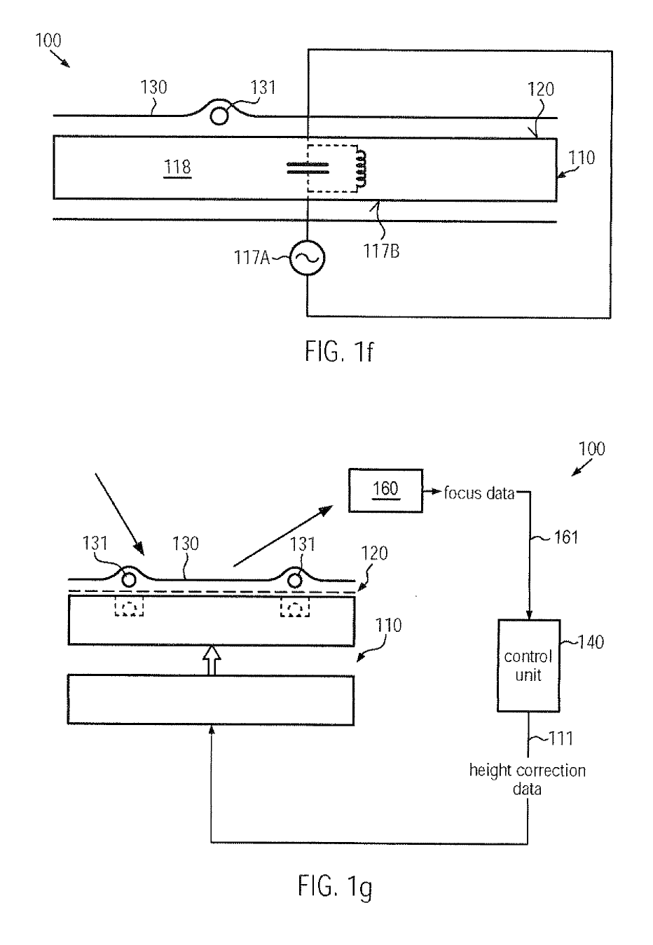

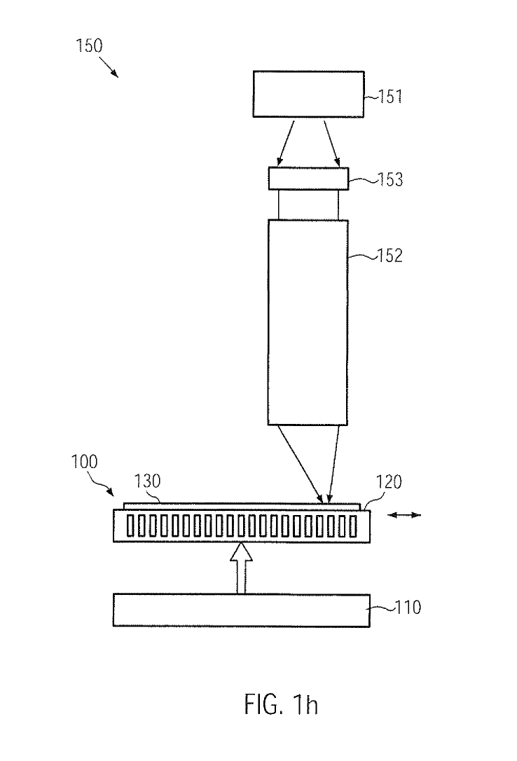

FIG. 1a schematically illustrates a cross-sectional view of a substrate support system 100, which is generally configured to receive and hold in place a substrate to be processed by a process tool, such as a lithography exposure tool, an imprint tool, or any other process tool for processing microstructure devices in which enhanced control of the local surface topography may be desirable. The system 100 may comprise a substrate support surface 120 on which a substrate 130 may be positioned and may be held in place, for instance by any appropriate attachment systems, such as vacuum units and the like, as is well known in the art for processing any substrates, such as semiconductor substrates and the like. The substrate support surface 120 may comprise a plurality of surface portions 121A, 121B . . . 121N which may also be collectively referred to as surface portions 121, if appropriate. It should be understood that each of the surface portions 121A, 121B . . . 121N is to be understood as a surface of a physical object which may be appropriate for placing thereon another physical object, such as a portion of the substrate 130. Furthermore, the surface portions 121 may be mechanically connected to an actuation system 110, which may be configured so as to individually vary a height position of each of the surface portions 121A, 121B . . . 121N. That is, the actuation system 110 is configured to perform any actions required for changing the height level of each of the surface portions 121A, 121B . . . 121N, which may be accomplished by modifying the mechanical state of a physical object providing the corresponding surface portions 121A, 121B . . . 121N. For instance, the actuation system 110 may be configured to modify an electrical field in a piezoelectric material, control the local temperature and thus the thermal expansion of a corresponding material, individually control individual actuator elements, such as miniature electric motors or any other electrically driven elements, or any other elements driven by other drive sources, such as hydraulic systems, pneumatic systems and the like. For example, in FIG. 1a, each of the surface portions 121A, 121B . . . 121N may be considered as a surface of an element which may change its length, its height position and the like upon an appropriate control activity of the actuation system 110.

As is illustrated in FIG. 1a, the substrate 130 may be positioned on the support surface 120, which, however, may result in a non-desired local surface topography, for instance due to the presence of particles 131, which may adhere to the substrate 130 and/or to the substrate support surface 120. For example, the system 100 may be used in an advanced lithography exposure tool so that the presence of even minute particles, such as the particle 131, may result in a significant local deviation of the height level of the substrate 130 so that a portion of the substrate 130 corresponding to the particle 131 may no longer be within an allowable range of the focus of the exposure tool, thereby resulting in a non-acceptable exposure of a portion in the vicinity of the particle 131. Even if the presence of a non-allowable height level may be detected prior to a corresponding exposure process, a compensation of the surface topography may frequently not be possible on the basis of conventional alignment systems in which typically the height position of the substrate 130 as a whole, in combination with two independent tilt angles, can be varied. According to the present disclosure, however, a significant variation of the local surface topography of the surface 120 may be accomplished, for instance in a range of approximately 5 μm and less, thereby providing the possibility of locally adapting the surface topography of the surface 120, thereby also providing the desired surface conditions on the substrate 130.

FIG. 1b schematically illustrates the system 100 when the surface topography of the support surface 120 may be adjusted by appropriately adapting the height level of respective surface portions 121. For instance, as illustrated, the surface portions 121C, 121D may have been identified as corresponding portions requiring an adaptation of the height position 122H to compensate for the presence of the particle 131. Consequently, an appropriate control signal 111 may be supplied to the actuation system 110 in order to initiate a variation of the height level to correspond to the desired target level 122H, which is considered appropriate for obtaining a desired surface topography. For instance, appropriate measurement data may be gathered after positioning the substrate 130 on the surface 120 and the corresponding target height level 122H for each of the surface portions 121A . . . 121N may be determined on the basis of the measurement data and the desired overall surface topography.

FIG. 1c schematically illustrates a top view of the actuation system 110 according to some illustrative embodiments. As shown, the actuation system 110 may comprise a piezoelectric material, which, in one illustrative embodiment, may be provided as a substantially continuous material in contact with the surface 120, while in other cases individual piezoelectric elements may be provided corresponding to the individual surface portions 121A . . . 121N. In the embodiment shown, the material 112 may be provided in a substantially continuous manner and may have a moderately high electric resistance so that an electrical field may be locally established within the material 112. For this purpose, in some illustrative embodiments, a plurality of electrodes 114A and 113A may define a corresponding “grid” within the material 112 in order to establish a corresponding local electrical field, which in turn may result in a corresponding contraction or expansion, depending on the magnitude and direction of the electric field. For example, the plurality of electrodes 114A, 113A may be provided as conductive lines, which may not be in contact with each other. Thus, at corresponding “intersections” 115, one of the electrodes 114A and one of the electrodes 113A may be close to each other, however without providing a direct contact, so that, by applying an appropriate voltage across corresponding pairs of electrodes 114A, 113A, a moderately high electric field and thus modification of the mechanical configuration may be accomplished. For this purpose, the electrodes 113A may be connected to a control unit 113 while the electrodes 114A may be connected to a control unit 114, which may select, upon an appropriate control signal, appropriate electrodes to be connected to a voltage source, wherein, in some illustrative embodiments, in addition to the polarity of the corresponding voltage, the magnitude thereof may also be controlled to provide a high degree of flexibility in individually adjusting the electrical field and thus the mechanical response of the piezoelectric material 112 at a respective intersection 115. It should be appreciated that a further advanced “wiring system” may be applied, if required, when an even further degree of decoupling of the control of individual intersections 115 is desired. In other cases, when individual piezoelectric elements are provided, these elements may be individually connected to a corresponding electrode pair, thereby enabling a high degree of individual controllability without influencing neighboring areas of the actuation system 110. It should be appreciated that a plurality of piezoelectric materials are available and may be used as the material 112, wherein the type of material, the magnitude of the voltage supplied thereto, as well as basic mechanical configuration, may define the available range of height adjustment capability, which may be approximately 5 μm and less for highly sophisticated applications. It should be appreciated, however, that an increased range of height adjustment may be provided in other cases when a “coarser” definition of the height level of the individual surface portions 121A . . . 121N may be considered appropriate.

FIG. 1d schematically illustrates a portion of the actuation system 110 according to still other illustrative embodiments. As illustrated, the system 110 may comprise a plurality of temperature adjustment elements in combination with a corresponding wiring system 117 so as to enable an individual control of each of the elements 116A, 116B . . . . For instance, the elements 116A, 116B . . . may be embedded into a material that has a pronounced coefficient of thermal expansion so that a corresponding local change of temperature may result in a corresponding change of volume and thus height of the material under consideration. For this purpose, in some illustrative embodiments, the elements 116A . . . may be provided in the form of resistive structures, the waste heat of which may be advantageously used for heating the surrounding in a local manner. In other illustrative embodiments, the elements 116A . . . may represent thermoelectric elements in which a heating and cooling effect may be accomplished by appropriately selecting the direction of current flow through the elements 116A . . . .

FIG. 1e schematically illustrates a cross-sectional view of the actuation system 110 of FIG. 1d. As illustrated, a material 118 may be provided with the desired thermal characteristics in view of the expansion coefficient, as previously explained, so as to obtain a desired adaptation of the volume and thus the height of the material 118 in a local manner. For example, as illustrated in FIG. 1e, individual cells 118A . . . may be provided in the material 118, wherein each cell may include a corresponding temperature adjustment element 116A (FIG. 1d) so that temperature control may be accomplished individually for each cell 118A . . . . The cells 118A . . . may be separated from a neighboring cell by a material 119A having an inferior thermal conductivity so that equalization in the thermal conditions between neighboring cells may be significantly slowed down to enable maintaining a corresponding temperature profile within the material 118 for a time period that is appropriate for processing the substrate 130. Moreover, in some illustrative embodiments, a material 119 of reduced thermal conductivity may also be provided above the material 118 in order to avoid significant heat transport from each of the cells 118A . . . into the substrate 130. Consequently, upon locally supplying electrical energy by the wiring system 117 to the cells 118A . . . , an appropriate temperature profile may be established across the cells 118A . . . , thereby also creating a corresponding surface profile as may be required for obtaining a target surface topography for processing the substrate 130.

FIG. 1f schematically illustrates the system 100 according to further illustrative embodiments in which the actuation system 110 may comprise the material 118 in the form of an appropriate dielectric material, possibly in combination with a ferrite material, in order to respond to high frequency energy or varying magnetic fields, depending on the configuration of the system 110. For example, the material 118 may represent a capacitor dielectric material which may be accomplished by appropriately adapting a thickness of the material 118 and using a material of high dielectric constant. On the other hand, the surface material 118 acting as the support surface 120 may have formed therein any appropriate conductive electrode system so as to allow the application of an AC voltage across the dielectric material 118. For example, a second electrode 117B may be provided as any appropriate metal layer, which may be connected to an AC generator 117A. On the other hand, the generator 117A may be connected to the surface 120. Thus, upon placing the substrate 130, the capacitance of the resulting capacitor structure provided by the electrode grid in the surface 120, dielectric material 118 and the electrode 117B may be influenced by the presence of the substrate 130 and may thus vary the electric field in the dielectric material 118. For example, due to the presence of the particle 131, a local variation of the electrical field may be obtained, thereby also locally varying the response of the material 118 with respect to energy supplied by the generator 117A. Thus, the energy deposition into the material 118 may locally vary corresponding to the surface topography of the substrate 130, thereby also obtaining a locally varying response of the material 118, for instance with respect to energy deposition, which in turn may result in a locally different degree of heating. For example, the local energy deposition in the vicinity of the particle 131 may be less compared to other areas in the material 118, thereby correspondingly increasing height of the areas surrounding the particle 131. Consequently, a certain degree of “self-compensation” of initially undesired surface topography may be accomplished. In some illustrative embodiments, the back side of the substrate 130 may be appropriately prepared in order to obtain a significant variation in capacitance, for instance by providing a high-k dielectric material layer on the back side thereof and the like.

FIG. 1g schematically illustrates the substrate support system 100 according to further illustrative embodiments. As illustrated, a measurement system 160 may be provided which may be configured to create measurement data 161 indicating a momentary surface topography of the substrate 130 positioned on the surface 120. For example, corresponding focus data may be obtained on the basis of automatic alignment procedures, as are frequently used in sophisticated lithography tools well known in the art. Corresponding focus data may have included therein information on the local levels of the substrate 130, which may vary and may exceed an allowable range due to the presence of particles 131 and the like. The corresponding measurement data 161 may be supplied to a control unit 140, which may be configured to determine an appropriate target value for the height levels at least at a plurality of positions across the surface 120, such as the target height positions of the plurality of surface portions 121A . . . 121N (see FIGS. 1a-1b). For example, the control unit 140 may be configured to determine appropriate target height levels on the basis of a comparison of measurement data corresponding to a plurality of different measurement positions in order to detect corresponding positions that may require compensation of the respective height levels. On the basis of the corresponding target height levels for the various positions in the surface 120, the control signal 111 may be established, for instance by providing any digital or analog signals to the actuation system 110, which in turn may create an appropriate drive signal for individually adjusting the height levels of the surface 120 based on the control signal 111. For example, as previously explained, respective electrical fields may be locally varied in accordance with the control signal 111 in order to appropriately adjust the mechanical response of any piezoelectric elements and the like, while in other cases a desired local temperature control may be accomplished. It should be appreciated that the control unit 140 may also have implemented therein appropriate calibration data, if required, so that the measurement data 161 including the information about the momentary height levels may be appropriately converted into the control signal 111. Thus, upon supplying the control signal 111, an appropriate height adjustment in a locally resolved manner may be accomplished, as is also indicated by the dashed lines, thereby avoiding any additional maintenance activity, which may be required in conventional systems upon detecting a non-allowable surface topography of the substrate 130.

FIG. 1h schematically illustrates an exposure system 150 in which the substrate support system 100 may be implemented in order to provide enhanced control of focus conditions during an exposure process. As illustrated, the exposure system 150 may comprise a radiation source 151 that may provide the desired radiation, such as ultraviolet radiation and the like, as is required for exposing the substrate 130 positioned on the surface 120 of the system 100. Moreover, an optical system 152 may be provided which, in combination with the radiation source 151, may define an imaging system of the exposure tool 150. For this purpose, a corresponding lithography mask 153 may be provided, which may contain corresponding mask features that may be imaged onto a radiation sensitive material provided on the substrate 130.

During operation of the exposure system 150, the substrate 130 may be positioned on the surface 120 and a corresponding momentary surface topography may be determined on the basis of corresponding measurement strategies, which may include automatic alignment and focus procedures, as are well established in the art in sophisticated exposure tools. It should be appreciated that, frequently, a second substrate support system 100 may be provided in the tool 150, thereby enabling the alignment and adjustment of the focus conditions while actually exposing a second substrate. Thus, upon receiving the measurement data, as is for instance described with reference to FIG. 1g, appropriate target height levels for various lateral positions in the surface 120 may be determined in order to obtain a desired surface topography. For instance, in advanced exposure tools, a step and scan system may be used in which an exposure slit may be scanned across a portion of the substrate 130, thereby defining a corresponding exposure field. Frequently, higher order focus errors may occur across the exposure slit, which may be difficult to be compensated for by conventional techniques based on a global adjustment of the height level of the substrate 130 and two independent tilt angles. Thus, based on the local height adjustment capability of the system 100, corresponding higher order focus errors may be compensated for or at least reduced. Thereafter, the exposure process may be performed on the basis of an enhanced surface topography, even if a significant variation may initially be detected due to contamination of the substrate 130 and/or of the surface 120 or due to any other focus errors.

As a result, the present disclosure provides techniques and systems in which an individual adaptation of height levels of a substrate support surface may be accomplished, thereby enhancing overall performance of corresponding process tools used for processing microstructure devices. In some illustrative embodiments, the substrate support system having the local height adjustment capability may be used in exposure tools, thereby enhancing overall performance thereof and also increasing tool utilization due to avoiding or at least significantly reducing any maintenance activities, which may conventionally be performed upon detecting a non-allowable local variation of the surface topography. Thus, the present disclosure may be efficiently applied to complex manufacturing tools for processing microstructure devices, such as integrated circuits, micromechanical devices, micro-optical devices and the like, in which a desired surface topography may be required.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A substrate support system of a process tool, comprising:
a plurality of support surface portions configured to receive a substrate to be processed, each of said plurality of support surface portions being individually adjustable in its height position; and
an actuation system connected to said plurality of support surface portions so as to initiate adjustment of the height position of each of said plurality of support surface portions on the basis of a control signal.

2. The substrate support system of claim 1, wherein said actuation system comprises a piezoelectric material and an electric interconnection system for locally adjusting a voltage level of said piezoelectric material.

3. The substrate support system of claim 1, wherein said actuation system comprises a material of increased thermal expansion coefficient and a temperature control system for locally controlling a temperature of said material of increased thermal expansion coefficient.

4. The substrate support system of claim 3, wherein said actuation system further comprises a thermally insulating material formed between said material of increased thermal expansion coefficient and said support surface portions.

5. The substrate support system of claim 1, wherein said actuation system comprises an individually operable actuator element for each of said plurality of support surface portions.

6. The substrate support system of claim 1, further comprising a control unit operatively connected to said actuation system and configured to provide said control signal on the basis of a target height for each of said plurality of support surface portions.

7. The substrate support system of claim 6, wherein said control unit is further configured to determine said target height of each of said plurality of support surface portions on the basis of measurement data indicating a momentary height position of said plurality of support surface portions.

8. The substrate support system of claim 7, further comprising a measurement system configured to obtain said measurement data.

9. The substrate support system of claim 1, wherein said actuation system is configured to adjust the height of each of said plurality of support surface portions in an adjustment height range of approximately 5 μm or less.

10. An exposure system, comprising:
an imaging unit comprising a radiation source and an optical system; and
a substrate support system configured to receive and hold in place a substrate to be exposed, said substrate support system comprising a plurality of support surface portions configured to receive a substrate to be exposed, each of said plurality of support surface portions being individually adjustable in its height position, and an actuation system connected to said plurality of support surface portions so as to initiate adjustment of the height position of each of said plurality of support surface portions on the basis of a control signal.

11. The exposure system of claim 10, further comprising a control unit operatively connected to said actuation system and configured to provide said control signal on the basis of a target height for each of said plurality of support surface portions.

12. The exposure system of claim 11, wherein said control unit is further configured to determine said target height of each of said plurality of support surface portions on the basis of a measurement data indicating a momentary height position of said plurality of support surface portions.

13. The exposure system of claim 12, further comprising a measurement system configured to obtain said measurement data.

14. The exposure system of claim 10, wherein said actuation system is configured to adjust the height of each of said plurality of support surface portions in an adjustment height range of approximately 5 μm or less.

15. A method of exposing a substrate, the method comprising:
receiving said substrate on a substrate support surface of a substrate support system;
individually adjusting a height level of at least one portion of said substrate support surface relative to at least one other portion of said substrate support surface; and
exposing said substrate on the basis of said individually adjusted height level of said at least one portion of said substrate support surface.

16. The method of claim 15, further comprising determining a target height of said at least one portion and adjusting said height level on the basis of said target height.

17. The method of claim 16, wherein determining said target height comprises obtaining measurement data indicating a height level of said at least one portion and said at least one other portion.

18. The method of claim 15, wherein individually adjusting a height level of at least one portion of said substrate support surface comprises locally controlling a temperature of a material that is in mechanical contact with said substrate support surface.

19. The method of claim 15, wherein individually adjusting a height level of at least one portion of said substrate support surface comprises locally controlling an electric field in a piezoelectric material that is in mechanical contact with said substrate support surface.

20. The method of claim 15, wherein individually adjusting a height level of at least one portion of said substrate support surface comprises providing an individual actuator element for each of a plurality of portions of said substrate support surface and individually activating one or more of said plurality of actuator elements.
